(19) United States
(12) Patent Application Publication
(10) Pub. No.: US 2009/0014868 A1
(43) Pub. Date: Jan. 15, 2009

(54) MANUFACTURING IC CHIP IN PORTIONS FOR LATER COMBINING, AND RELATED STRUCTURE

(75) Inventors: Karl W. Barth, Poughkeepsie, NY (US); Kaushik A. Kumar, Beacon, NY (US); Kevin S. Petrarca, Newburgh, NY (US); Victoria J. Sternhagen, Uppsala (SE)

Correspondence Address: HOFFMAN WARNICK LLC, 75 STATE ST, 14TH FL, ALBANY, NY, 12207, US

(73) Assignee: INTERNATIONAL BUSINESS MACHINES CORPORATION, Armonk, NY (US)

(21) Appl. No.: 11/775,464

(22) Filed: Jul. 10, 2007

(51) Int. Cl. H01L 21/02; H01L 23/48

(52) U.S. Cl. 257/735; 438/107; 257/E25.03; 257/E23.172; 257/E21.705

(57) ABSTRACT

Methods of manufacturing an IC chip in portions for later combining and a related structure are disclosed. In one embodiment, the method includes: fabricating a first portion of the IC chip, the first portion including a structure from a selected level of back-end-of-line (BEOL) processing up to an end of the BEOL processing, the first portion providing a specific functionality when combined with a second portion of the IC chip, fabricating the second portion of the IC chip, the second portion including a structure from a device level of the IC chip up to the selected level of the BEOL processing, the second portion having structure providing generic IC chip functionality. The fabrication of the portions may occur at a single location or different locations, and the combining may occur at the same location or different location as one or more of the fabrication processes.

### BACKGROUND

1. Technical Field

The disclosure relates generally to integrated circuit (IC) chip fabrication, and more particularly, to a method of manufacturing an IC chip and a related structure.

2. Background Art

Fabrication of IC chips is an extremely complex process that requires advanced technology and expertise. One continuous challenge in IC chip fabrication is maintaining a good yield. Typically, front-end-of-line (FEOL) processing of an IC chip, i.e., operations performed on the semiconductor wafer in the course of device manufacturing up to first metallization, requires very advanced technology and expertise to maintain yield. Hence, most of the expense of fabrication is focused on the FEOL levels. In contrast, back-end-of-line (BEOL) processing, i.e., operations performed on the semiconductor wafer in the course of device manufacturing after first metallization, do not require as advanced technology and expertise. As a result, the BEOL processing is not as expensive. Typically, yield results are not known until after an IC chip is completed. Although BEOL layers are not costly to fabricate, yield problems that are caused in the BEOL layers are especially costly since they may lead to discarding of a satisfactory FEOL that costs more to fabricate. The BEOL processing is oftentimes the location in which the IC chip's specific functionality is provided. That is, the wiring structure to provide a specific function, e.g., set top box functionality, gaming functionality, personal computer functionality, etc., is normally provided in the BEOL.

### SUMMARY

Methods of manufacturing an IC chip in portions for later combining and a related structure are disclosed. In one embodiment, the method includes: fabricating a first portion of the IC chip, the first portion including a structure from a selected level of back-end-of-line (BEOL) processing up to an end of the BEOL processing, the first portion providing a specific functionality when combined with a second portion of the IC chip, fabricating the second portion of the IC chip, the second portion including structure from a device level of the IC chip up to the selected level of the BEOL processing, the second portion having a structure providing generic IC chip functionality. The fabrication of the portions may occur at a single location or different locations, and the combining may occur at the same location or different location as one or more of the fabrication processes.

A first aspect of the disclosure provides a method of manufacturing an integrated circuit (IC) chip, the method comprising: fabricating a first portion of the IC chip, the first portion including a structure from a selected level of back-end-of-line (BEOL) processing up to an end of the BEOL processing, the first portion providing a specific functionality when combined with a second portion of the IC chip, fabricating the second portion of the IC chip, the second portion including structure from a device level of the IC chip up to the selected level of the BEOL processing, the second portion having a structure providing generic IC chip functionality; and combining the first portion and the second portion to form the IC chip.

A second aspect of the disclosure provides a structure comprising: at least one dielectric layer including electrical elements structured to provide a specific function for an IC chip when coupled to a base portion of the IC chip that provides a generic function; and a plurality of connectors adapted to couple to the at least one dielectric layer to the base portion in such a manner to form a complete IC chip.

A third aspect of the disclosure provides a method comprising: fabricating a first portion of an integrated circuit (IC) chip, the first portion including a structure from a selected level of back-end-of-line (BEOL) processing up to an end of the BEOL processing, the first portion providing a specific functionality when combined with a second portion of the IC chip that includes a structure from a device level of the IC chip up to the selected level of the BEOL processing and provides generic IC chip functionality; and forwarding the first portion for combining with the second portion to form the IC chip.

A fourth aspect of the disclosure is directed to a method of manufacturing an integrated circuit (IC) chip, the method comprising: receiving a first portion of the IC chip, the first portion including a structure from a selected level of back-end-of-line (BEOL) processing up to an end of the BEOL processing, the first portion providing a specific functionality when combined with a second portion of the IC chip that includes a structure from a device level of the IC chip up to the selected level of the BEOL processing and provides generic IC chip functionality; receiving the second portion of the IC chip; and combining the first portion and the second portion to form the IC chip.

The illustrative aspects of the present disclosure are designed to solve the problems herein described and/or other problems not discussed.

### BRIEF DESCRIPTION OF THE DRAWINGS

These and other features of this disclosure will be more readily understood from the following detailed description of the various aspects of the disclosure taken in conjunction with the accompanying drawings that depict various embodiments of the disclosure, in which:

FIG. 1 shows a cross-sectional view of a method of manufacturing and a related structure according to the disclosure.

FIG. 2 & FIG. 3 show perspective views of a process of combining according to the method of FIG. 1.

It is noted that the drawings of the disclosure are not to scale. The drawings are intended to depict only typical aspects of the disclosure, and therefore should not be considered as limiting the scope of the disclosure. In the drawings, like numbering represents like elements between the drawings.

### DETAILED DESCRIPTION

Methods of manufacturing an IC chip 120 (FIG. 3) in portions for later combining and a related structure are disclosed. The methods described herein should not be confused with three dimensional (3D) integration in which finished IC chips are packaged. The methods described herein are for finishing a single IC chip. As used herein, “fabrication” and “manufacturing” are used synonymously.

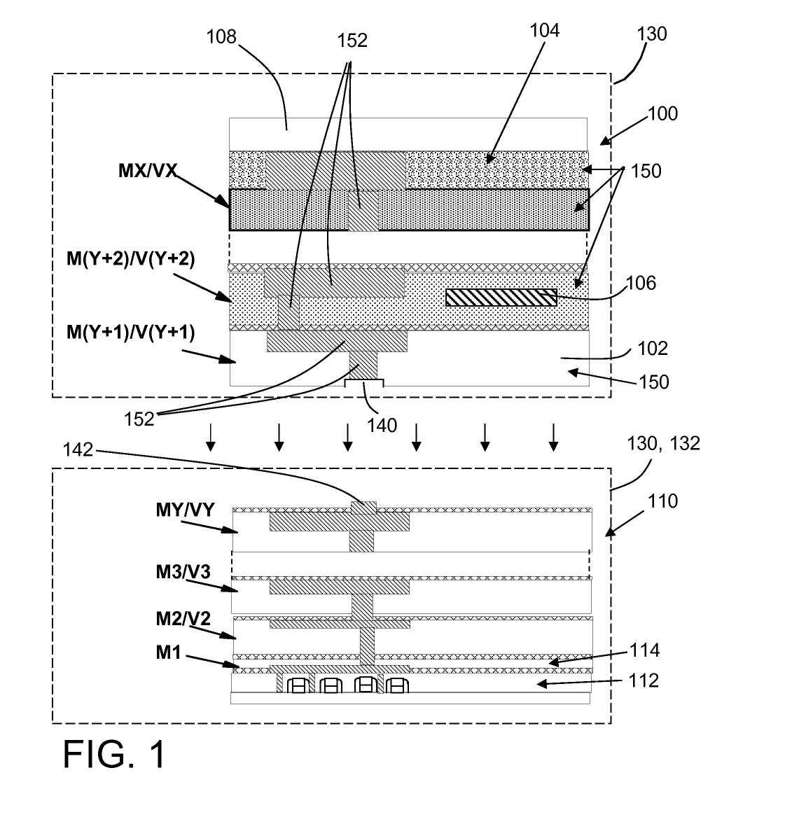

Turning to FIG. 1, embodiments of the method include generally fabricating a first portion 100 of IC chip 120 (FIG. 3) including structure from a selected level 102 of back-end-of-line (BEOL) processing up to an end 104 (MX/VX) of the BEOL processing, and separately fabricating a second portion 110 of the IC chip, the second portion 110 including a structure from a device level 112 of the IC chip up to selected level 102 of the BEOL processing. Each fabrication process may include using any now known or later developed techniques and equipment. In one embodiment, first portion 100 fabricating includes fabricating the first portion on a substrate 108, e.g., bulk silicon, silicon on insulator, aluminum oxide (AlO₂), ceramics, III-V semiconductor or compound semiconductor material, etc., having a coefficient of thermal expansion (CTE) substantially matching (or at least compatible) with second portion 110 to prevent possible structural issues when combined. First portion 100 includes at least one dielectric layer 150 including electrical elements 152 (e.g., wires, vias, electrical devices 106, etc.) structured to provide a specific function for IC chip 120 (FIG. 3) when coupled to a base (second) portion 110 of the IC chip that provides a generic function. Electrical device(s) 106 may include, but are not limited to: memory, passive elements (e.g., coils, capacitors, etc.) or active structures such as micro electromechanical systems (MEMS). First portion 110 also includes a plurality of connectors (140 as shown in FIG. 1) adapted to couple to the plurality of dielectric layers to the base (second) portion 110 in such a manner to form a complete IC chip 120. Base (second) portion 110 includes complementary connectors (142 as shown in FIG. 1).

As shown in FIG. 1, first portion 100 and second portion 110 may be fabricated at a single first location 130. Alternatively, first portion 100 may fabricated at first location 130 and second portion 110 may be fabricated at a second, different location 132. In this case, first location 130 may include fabrication equipment known to those skilled in the art that is less advanced and requires less expertise than that used to fabricate second portion 110 at second, different location 132. That is, second portion 110 includes front-end-of-line devices, e.g., transistors, that require very precise processes to manufacture such as immersion DUV lithography, ALD metal definition including rare earth metals, angstrom level control of film thickness deposition and etch. In contrast, first portion 100 may only require processes such as line lithography, large tolerance depositions and etches. It is understood that the different locations 130, 132 may be different sites within an area that may be considered a single factory, or may be more substantively separated geographically, e.g., different cities, states/provinces, countries, continents, etc.

Selected level 102 may be selected based on the application for IC chip 120 (FIG. 3). In one embodiment, first portion 100 may include only those wires that are referred to as “fat wires”, i.e., a wire that is twice the width or greater of the minimum wire width in a given technology (e.g., greater than 150 nm for a current technology). The size of wires referred to as “fat wires” may vary over time, technology level and according to IC chip application. In any case, second portion 110 may include, for example, device (FEOL) layer 112, middle-of-line (MOL) layer 114 and BEOL “thin wire” layer(s) (M2/V2 to MY/VY). First portion 100 may include BEOL “fat wire” layers M(Y+1)N(Y+1) to end 104 (MX/VX) of the BEOL. The value of MX/VX will vary depending on IC chip application. First portion 100 provides a specific functionality when combined with second portion 110 of the IC chip, the latter of which has structure providing generic IC chip functionality. As such, first portion 100 can be used to personalize IC chip 120 therefore leaving second portion 110, i.e., device layer 112, MOL layer 114 and BEOL thin wire layers (M2/V2 to MY/VY), mainly the same for all IC chips.

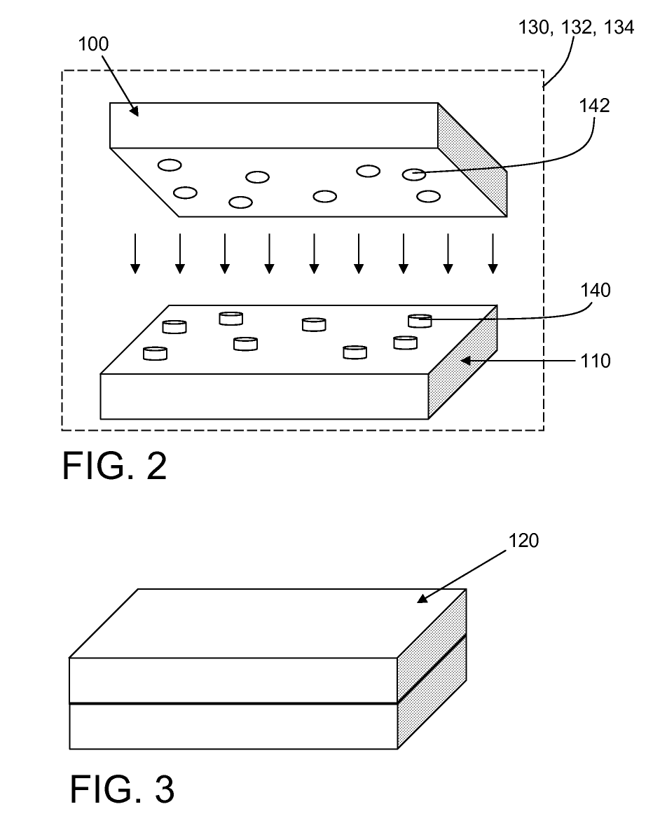

FIG. 2 shows combining first portion 100 and second portion 110 to form IC chip 120 (FIG. 3). The attachment of first portion 100 to second portion 110 can be by any now known or later developed connection. In one embodiment, first portion 100 and second portion 110 each include a plurality of mating connectors 140, 142. For example, mating connectors 140, 142 may include a plurality of male connectors 140 on one of first portion 100 and second portion 110 and a plurality of mating female connectors 142 on the other of first portion 100 and second portion 110. However, the disclosure is not limited to any particular type of connector or joining technique and any now known or later developed are considered within the scope of the disclosure. Current illustrative techniques include: noble metal thermal compression joints (e.g., gold), copper studs, controlled collapse chip connection (C4) or lead free type connectors. In one embodiment, prior to combining, first portion 100 may be tested using any now known or later developed technique to determine whether the first portion is operational.

The combining may occur at first location 130, second, different location 132, or at a third location 134 different than first location 130 and second location 132. Where the combining location is different than where first portion 100 and/or second portion 110 is fabricated, then the respective portion(s) 100, 110 are forwarded to and received at the combining location. Where the combining occurs at a single location with one or more of the fabricating processes, forwarding may occur within that single location. It is understood that the different locations 130, 132, 134 may be different sites within an area that may be considered a single factory, or may be more substantively separated geographically, e.g., different cities, states/provinces, countries, continents, etc.

The fact that second portion 110 are the same for all IC chips provides an economy of scale in that second portion 110 can be fabricated to higher tolerances at higher costs, while first portion 100 is fabricated to lesser tolerances and at lower costs and complexity, perhaps at a different location providing lower costs of manufacture. In addition, first portion 100 including the final BEOL layers separated from second portion 110 as a discrete attachable component allows for limiting the yield loss on the full build IC chip. Also, first portion 100 allows for personalization of second portion 110 and IC chip 120 dependant on costumer needs and requirements.

The methods and structure as described above are used in the fabrication of an integrated circuit chip. The resulting integrated circuit chip and/or portions thereof can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a circuit board or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a circuit board, or (b) an end product. The end product can be any product that includes integrated circuit chips, ranging from toys and other low-end applications to advanced computer products having a display, a keyboard or other input device, and a central processor.

The foregoing description of various aspects of the disclosure has been presented for purposes of illustration and description. It is not intended to be exhaustive or to limit the disclosure to the precise form disclosed, and obviously, many modifications and variations are possible. Such modifications and variations that may be apparent to a person skilled in the art are intended to be included within the scope of the disclosure as defined by the accompanying claims.

What is claimed is:

1. A method of manufacturing an integrated circuit (IC) chip, the method comprising:
fabricating a first portion of the IC chip, the first portion including structure from a selected level of back-end-of-line (BEOL) processing up to an end of the BEOL processing, the first portion providing a specific functionality when combined with a second portion of the IC chip,
fabricating the second portion of the IC chip, the second portion including a structure from a device level of the IC chip up to the selected level of the BEOL processing, the second portion having a structure providing generic IC chip functionality; and
combining the first portion and the second portion to form the IC chip.

2. The method of claim 1, wherein the first portion includes at least one electrical device.

3. The method of claim 2, wherein the electrical device includes at least one of: memory, passive element or analog-to-mixed signal structure.

4. The method of claim 1, wherein the first portion fabricating occurs at a first location and the second portion fabricating occurs at a second, different location, wherein the second, different location includes a more advanced fabrication site than the first location.

5. The method of claim 4, wherein the combining occurs at a third location different than the first location and the second, different location.

6. The method of claim 1, wherein the first portion and the second portion each includes a plurality of mating connectors.

7. The method of claim 6, wherein the mating connectors include a plurality of male connectors on one of the first portion and the second portion and a plurality of mating female connectors on the other of the first portion and the second portion.

8. The method of claim 1, further comprising testing the first portion to determine whether the first portion is operational prior to the combining.

9. The method of claim 1, wherein the first portion fabricating includes fabricating the first portion on a substrate having a coefficient of thermal expansion substantially matching the second portion.

10. A structure comprising:
at least one dielectric layer including electrical elements structured to provide a specific function for an IC chip when coupled to a base portion of the IC chip that provides a generic function; and
a plurality of connectors adapted to couple to the at least one dielectric layer to the base portion in such a manner to form a complete IC chip.

11. The structure of claim 10, wherein the at least one dielectric layer is mounted to a substrate having a coefficient of thermal expansion (CTE) substantially matching that of the base portion.

12. The structure of claim 11, wherein the substrate is selected from the group consisting of: bulk silicon, silicon on insulator, aluminum oxide (AlO₂), ceramics, III-V semiconductor or compound semiconductor material.

13. The structure of claim 10, wherein the plurality of connectors includes a plurality of mating connectors for the base portion.

14. The structure of claim 13, wherein the plurality of mating connectors includes one of a plurality of male connectors and a plurality of female connectors.

15. The structure of claim 10, wherein the electrical elements includes wiring and vias.

16. The structure of claim 15, wherein the electrical elements include at least one electrical device.

17. The structure of claim 16, wherein the at least one electrical device includes at least one of: memory, passive element or analog-to-mixed signal structure.

18. A method comprising:
fabricating a first portion of an integrated circuit (IC) chip, the first portion including structure from a selected level of back-end-of-line (BEOL) processing up to an end of the BEOL processing, the first portion providing a specific functionality when combined with a second portion of the IC chip that includes structure from a device level of the IC chip up to the selected level of the BEOL processing and provides generic IC chip functionality; and
forwarding the first portion for combining with the second portion to form the IC chip.

19. The method of claim 18, wherein the forwarding occurs within a single location, and wherein the combining occurs at the single location.

20. A method of manufacturing an integrated circuit (IC) chip, the method comprising:
receiving a first portion of the IC chip, the first portion including a structure from a selected level of back-end-of-line (BEOL) processing up to an end of the BEOL processing, the first portion providing a specific functionality when combined with a second portion of the IC chip that includes a structure from a device level of the IC chip up to the selected level of the BEOL processing and provides generic IC chip functionality;
receiving the second portion of the IC chip; and
combining the first portion and the second portion to form the IC chip.
